(19) United States
(12) Patent Application Publication
(10) Pub. No.: US 2024/0162263 A1
(43) Pub. Date: May 16, 2024

(54) IMAGING DEVICE

(71) Applicant: SONY SEMICONDUCTOR SOLUTIONS CORPORATION, KANAGAWA (JP)

(72) Inventor: CHIE TOKUMITSU, KANAGAWA (JP)

(21) Appl. No.: 18/549,178

(22) PCT Filed: Mar. 4, 2022
(86) PCT No.: PCT/JP2022/009274

§ 371 Date: Sep. 6, 2023

(30) Foreign Application Priority Data
Mar. 18, 2021 (JP) 2021-044892

(51) Int. Cl. H01L 27/146

(52) U.S. Cl. CPC H01L 27/1463; H01L 27/14627; H01L 27/14634; H01L 27/14636; H01L 27/1464; H01L 27/14645; H01L 27/14683

(57) ABSTRACT

To provide an imaging device that can suppress color mixing between pixels. An imaging device includes a first semiconductor substrate having a plurality of photoelectric conversion elements, a lens body provided on one surface side of the first semiconductor substrate, and a wiring layer provided on an opposite side of the one surface of the first semiconductor substrate. The first semiconductor substrate includes an inter-element isolation part disposed between one photoelectric conversion element and another photoelectric conversion element adjacent to each other among the plurality of photoelectric conversion elements. The wiring layer includes a first isolation part disposed at a position facing the inter-element isolation part. The first isolation part includes a first low refractive index region and a first high refractive index region in contact with the first low refractive index region. The first high refractive index region sandwiches the first low refractive index region from both sides.

### TECHNICAL FIELD

The present disclosure relates to an imaging device.

### BACKGROUND ART

A back-illuminated solid-state imaging device typified by a complementary metal oxide semiconductor (CMOS) image sensor includes, for example, a photoelectric conversion unit such as a photodiode, and a wiring layer disposed on the opposite side of a light incident surface of the photoelectric conversion unit. The photoelectric conversion unit is provided on the substrate. The back surface of the substrate is the light incident surface.

In the conventional solid-state imaging device, there is a case where light transmitted through a photoelectric conversion unit of one pixel is reflected by a wiring layer or the like and reaches a photoelectric conversion unit of another pixel. In this case, color mixing may occur between one pixel and another pixel. In order to prevent such color mixing, a method is known in which a high refractive index region is provided below the photoelectric conversion unit to reduce the color mixing by a difference in refractive index. (Refer to, for example, Patent Document 1.)

### CITATION LIST

### Patent Document

Patent Document 1: Japanese Patent Application Laid-Open No. 2014-86551

### SUMMARY OF THE INVENTION

### Problems to be Solved by the Invention

In an imaging device disclosed in Patent Document 1, when light obliquely enters a substrate, there is a possibility that the light transmitted through a photoelectric conversion unit of one pixel enters a photoelectric conversion unit of another pixel adjacent to the one pixel. Furthermore, there has been a possibility that the light transmitted through a region other than the photoelectric conversion unit in one pixel is reflected by a wiring line or the like and enters the photoelectric conversion unit of another pixel. In either case, the color mixing occurs in a pixel signal between one pixel and another pixel, and there is a possibility that the performance of the imaging device is deteriorated.

The present disclosure has been made in view of such circumstances, and an object thereof is to provide an imaging device that can suppress the color mixing between the pixels.

### Solutions to Problems

An imaging device according to one aspect of the present disclosure includes a first semiconductor substrate having a plurality of photoelectric conversion elements, a lens body provided on one surface side of the first semiconductor substrate, and a wiring layer provided on an opposite side of the one surface of the first semiconductor substrate. The first semiconductor substrate includes an inter-element isolation part disposed between one photoelectric conversion element and another photoelectric conversion element adjacent to each other among the plurality of photoelectric conversion elements. The wiring layer includes a first isolation part disposed at a position facing the inter-element isolation part. The first isolation part includes a first low refractive index region and a first high refractive index region in contact with the first low refractive index region. The first high refractive index region sandwiches the first low refractive index region from both sides.

With this arrangement, the light incident on the first high refractive index region of the first isolation part is reflected at a boundary between the first high refractive index region and the first low refractive index region due to a difference in refractive index between the first high refractive index region and the first low refractive index region. Therefore, the first isolation part can suppress the light incident on the one pixel from entering the another pixel through the wiring layer. By including the first isolation part, the imaging device can easily confine the light incident on the one pixel in the one pixel, which enables the color mixing between pixels to be suppressed.

### BRIEF DESCRIPTION OF DRAWINGS

FIG. 1 is a block diagram illustrating a configuration example of an imaging device according to a first embodiment of the present disclosure.

FIG. 2 is a cross-sectional view illustrating a configuration example of the imaging device according to the first embodiment of the present disclosure.

FIG. 3 is a plan view illustrating a configuration example of an isolation part according to the first embodiment of the present disclosure.

FIG. 4 is a partially enlarged cross-sectional view of the imaging device according to the first embodiment of the present disclosure, and is a view illustrating a reflection example of light that has passed through the semiconductor substrate and entered the wiring layer.

FIG. 5 is a cross-sectional view illustrating a manufacturing method of the imaging device according to the first embodiment of the present disclosure in order of steps.

FIG. 6 is a cross-sectional view illustrating the manufacturing method of the imaging device according to the first embodiment of the present disclosure in order of steps.

FIG. 7 is a cross-sectional view illustrating the manufacturing method of the imaging device according to the first embodiment of the present disclosure in order of steps.

FIG. 8 is a cross-sectional view illustrating a manufacturing method of an imaging device according to a second embodiment of the present disclosure in order of steps.

FIG. 9 is a cross-sectional view illustrating the manufacturing method of the imaging device according to the second embodiment of the present disclosure in order of steps.

FIG. 10 is a cross-sectional view illustrating a configuration example of the imaging device according to the second embodiment of the present disclosure.

FIG. 11 is a cross-sectional view illustrating a manufacturing method of an imaging device according to a third embodiment of the present disclosure in order of steps.

FIG. 12 is a cross-sectional view illustrating the manufacturing method of the imaging device according to the third embodiment of the present disclosure in order of steps.

FIG. 13 is a cross-sectional view illustrating a configuration example of the imaging device according to a first modification of the present disclosure.

FIG. 14 is a cross-sectional view illustrating a configuration example of the imaging device according to a second modification of the present disclosure.

### MODE FOR CARRYING OUT THE INVENTION

Hereinafter, embodiments of the present disclosure are described with reference to the drawings. In the description of the drawings referred to in the following description, the same or similar parts are denoted by the same or similar reference signs. However, it should be noted that the drawings are schematic, and a relationship between a thickness and a planar dimension, a ratio of the thicknesses between respective layers, and the like are different from the actual ones. Therefore, specific thicknesses and dimensions should be determined in consideration of the following description. Furthermore, it goes without saying that dimensional relationships and ratios are partly different between the drawings.

Furthermore, definition of directions such as upward and downward in the following description is merely the definition for convenience of description, and does not limit the technical idea of the present disclosure. For example, it goes without saying that if a target is observed while being rotated by 90°, the upward and downward directions are converted into rightward and leftward, and if the target is observed while being rotated by 180°, the upward and downward are inverted.

In the following description, there is a case where the direction is described using terms such as an X-axis direction, a Y-axis direction, and a Z-axis direction. For example, the X-axis direction and the Y-axis direction are directions parallel to a back surface 50a of a semiconductor substrate 50. The X-axis direction and the Y-axis direction are also referred to as horizontal directions. The Z-axis direction is a normal direction to the back surface 50a of the semiconductor substrate 50. The X-axis direction, the Y-axis direction, and the Z-axis direction are orthogonal to each other.

### First Embodiment

(Configuration Example of Imaging Device)

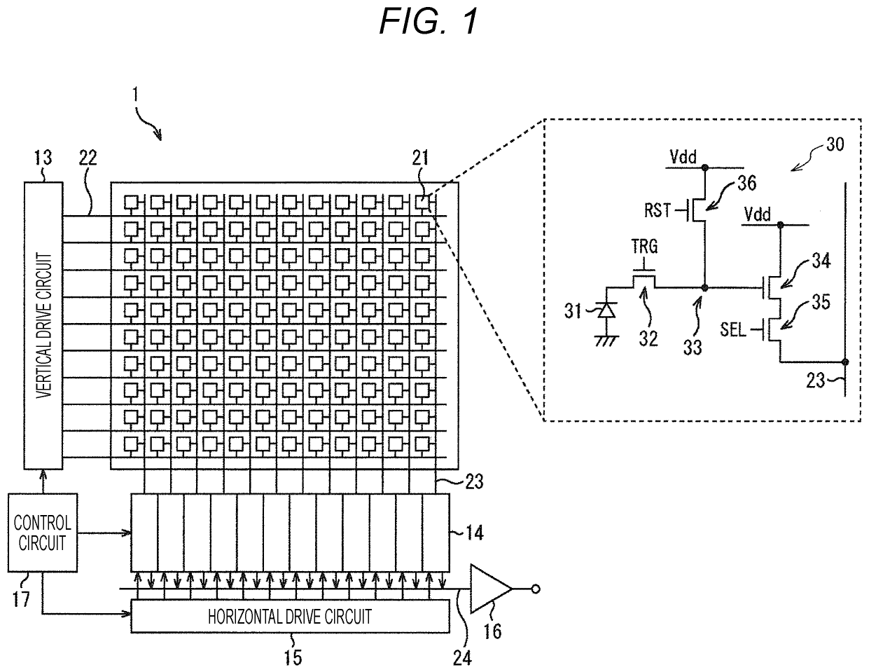

FIG. 1 is a block diagram illustrating a configuration example of an imaging device 1 according to the first embodiment of the present disclosure. As illustrated in FIG. 1, the imaging device 1 includes a plurality of pixels 21, a vertical drive circuit 13, a column signal processing circuit 14, a horizontal drive circuit 15, an output circuit 16, and a control circuit 17.

The pixel 21 is a light receiving region that receives light condensed by a not-illustrated optical system. The plurality of pixels 21 is arranged in a matrix. The plurality of pixels 21 is connected to the vertical drive circuit 13 for every row via the horizontal signal lines 22, and is connected to the column signal processing circuit 14 for every column via the vertical signal lines 23. The plurality of pixels 21 outputs pixel signals at levels corresponding to an amount of light respectively received. An image of a subject is constructed from these pixel signals.

The vertical drive circuit 13 sequentially supplies drive signals for driving (such as transferring, selecting, and resetting) the respective pixels 21 for every row of the plurality of pixels 21 to the pixels 21 via the horizontal signal lines 22. By performing correlated double sampling (CDS) processing on the pixel signals output from the plurality of pixels 21 via the vertical signal lines 23, the column signal processing circuit 14 performs analog-to-signal (AD) conversion on the pixel signals and removes reset noise.

The horizontal drive circuit 15 sequentially supplies the column signal processing circuit 14 with drive signals for causing the column signal processing circuit 14 to output the pixel signals to a data output signal line 24 for every column of the plurality of pixels 21. The output circuit 16 amplifies the pixel signals supplied from the column signal processing circuit 14 via the data output signal line 24 at a timing according to the drive signals of the horizontal drive circuit 15, and outputs the amplified pixel signals to a signal processing circuit of a subsequent stage. The control circuit 17 controls driving of respective blocks inside the imaging device 1. For example, the control circuit 17 generates a clock signal according to a drive cycle of each block and supplies the clock signals to the respective blocks.

The pixel 21 includes a photodiode 31 (an example of a “photoelectric conversion element” of the present disclosure), a transfer transistor 32, a floating diffusion 33, an amplification transistor 34, a select transistor 35, and a reset transistor 36. The transfer transistor 32, the floating diffusion 33, the amplification transistor 34, the select transistor 35, and the reset transistor 36 constitute a read circuit 30 that reads charge (pixel signal) photoelectrically converted by the photodiode 31.

The photodiode 31 is a photoelectric conversion unit that converts incident visible light into charge with photoelectric conversion and stores the charge, and has an anode terminal grounded and a cathode terminal connected to the transfer transistor 32. The transfer transistor 32 is driven in accordance with a transfer signal TRG supplied from the vertical drive circuit 13, and when the transfer transistor 32 is turned on, the charge stored in the photodiode 31 is transferred to the floating diffusion 33. The floating diffusion 33 is a floating diffusion region connected to a gate electrode of the amplification transistor 34 and having a predetermined storage capacitance, and temporarily stores the charge transferred from the photodiode 31.

The amplification transistor 34 outputs the pixel signal at a level (that is, a potential of the floating diffusion 33) corresponding to the charge stored in the floating diffusion 33 to the vertical signal line 23 via the select transistor 35. That is, with a configuration in which the floating diffusion 33 is connected to the gate electrode of the amplification transistor 34, the floating diffusion 33 and the amplification transistor 34 function as a conversion unit that amplifies the charge generated in the photodiode 31 and converts the charge into the pixel signal at a level corresponding to the charge.

The select transistor 35 is driven in accordance with a select signal SEL supplied from the vertical drive circuit 13, and when the select transistor 35 is turned on, the pixel signal output from the amplification transistor 34 can be output to the vertical signal line 23. The reset transistor 36 is driven in accordance with a reset signal RST supplied from the vertical drive circuit 13, and when the reset transistor 36 is turned on, the charge stored in the floating diffusion 33 is discharged to a drain power supply Vdd, and the floating diffusion 33 is reset.

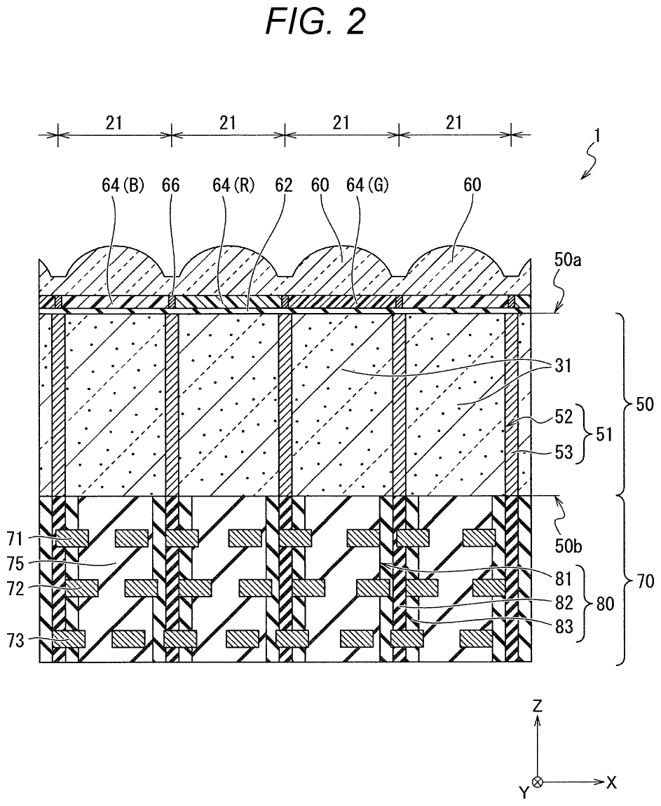

FIG. 2 is a cross-sectional view illustrating a configuration example of the imaging device 1 according to the first embodiment of the present disclosure. The imaging device 1 illustrated in FIG. 2 is, for example, a back-illuminated CMOS image sensor that photoelectrically converts light incident from the side of a back surface 50a (an example of a “one surface” of the present disclosure) of a semiconductor substrate 50 (an example of a “first semiconductor substrate” of the present disclosure).

The imaging device 1 includes the semiconductor substrate 50, a plurality of microlenses 60 (an example of a “lens body” of the present disclosure) provided on the back surface 50a side of the semiconductor substrate 50, and a wiring layer 70 provided on the side of a front surface 50b of the semiconductor substrate 50. Hereinafter, the back surface 50a of the semiconductor substrate 50 is also referred to as a light-receiving surface.

The semiconductor substrate 50 includes, for example, a silicon substrate formed by polishing a silicon wafer by chemical mechanical polishing (CMP). In the semiconductor substrate 50, the photodiode 31 is provided for each of the pixels 21. The thickness of the semiconductor substrate 50 may be optionally set according to the wavelength of the received light. As an example, the thickness of the semiconductor substrate 50 is 5 μm or more and 15 μm or less in a case of receiving the visible light, 15 μm or more and 50 μm or less in a case of receiving the infrared light, and 3 μm or more and 7 μm or less in a case of receiving ultraviolet light.

An insulating film 62 is provided on the back surface (for example, the light-receiving surface) 50a of the semiconductor substrate 50. The insulating film 62 includes, for example, a silicon oxide (SiO₂) film. A color filter 64 is provided on the insulating film 62. For example, the color filter 64 may be colored in any one of blue (B), green (G), and red (R), or may be colored in another color other than these colors. In FIG. 2, the blue color filter 64 is denoted by a reference numeral 64(B), the green color filter 64 is denoted by a reference numeral 64(G), and the red color filter 64 is denoted by a reference numeral 64(R). The color filter 64 is disposed at a position facing the photodiode 31 with the insulating film 62 interposed therebetween.

Furthermore, a partition wall 66 is provided on the light-receiving surface 50a of the semiconductor substrate 50 with the insulating film 62 interposed therebetween. The partition wall 66 is disposed between the adjacent pixels 21. The color filter 64 is isolated by the partition wall 66 for each pixel 21. The partition wall 66 includes a material having a light shielding property, and includes, for example, metal, black resin, or the like.

The microlenses 60 are provided on the light-receiving surface 50a with the insulating film 62 and the color filters 64 interposed therebetween. For example, one microlens 60 is disposed on one color filter 64. Ends of the adjacent microlenses 60 are connected to each other to form one microlens array to constitute one microlens array.

As illustrated in FIG. 2, the semiconductor substrate 50 is provided with an inter-pixel isolation part 51 (an example of an “inter-element isolation part” of the present disclosure). The inter-pixel isolation part 51 is disposed between the pixels 21 (that is, between one photodiode 31 and the other photodiode 31 adjacent to each other). A space between the adjacent photodiodes 31 is electrically isolated by the inter-pixel isolation part 51. The inter-pixel isolation part 51 is formed so as to surround the pixel 21, for example, formed in a lattice shape when viewed from the Z-axis direction.

The inter-pixel isolation part 51 has a trench isolation structure. For example, the inter-pixel isolation part 51 has a trench 511 formed in a depth direction from the back surface (for example, the light-receiving surface) 50a side of the semiconductor substrate 50, and a filling film 513 embedded in the trench 511. The filling film 513 includes, for example, an insulating film such as a SiO₂ film or a polysilicon film. The filling film 513 includes a material having a refractive index different from that of the semiconductor substrate 50. Furthermore, the filling film 513 may be a metal film embedded in the trench 511 with the insulating film interposed therebetween. The filling film 513 may have a fixed charge film provided so as to be in contact with an inner surface of the trench 511.

The wiring layer 70 includes a plurality of wiring lines (for example, a first wiring line 71 (an example of a “wiring line” in the present disclosure), a second wiring line 72, and a third wiring line 73), an interlayer insulating film 75 covering the wiring lines, and an isolation part 80 (an example of a “first isolation part” of the present disclosure). The first wiring line 71, the second wiring line 72, and the third wiring line 73 are laminated in a direction (for example, in the Z-axis direction) orthogonal to the direction (for example, in the X-axis direction and the Y-axis direction) in which one photodiode 31 and the other photodiode 31 are adjacent to each other. Among the first wiring line 71, the second wiring line 72, and the third wiring line 73, the interlayer insulating film 75 is disposed between one wiring line and the other wiring line facing each other in the Z-axis direction. For example, the interlayer insulating film 75 is disposed between the first wiring line 71 and the second wiring line 72 and between the second wiring line 72 and the third wiring line 73. The first wiring line 71, the second wiring line 72, and the third wiring line 73 are each covered with the interlayer insulating film 75.

For example, the first wiring line 71, the second wiring line 72, and the third wiring line 73 include metal such as aluminum (Al) or copper (Cu). The interlayer insulating film 75 includes an insulation film such as a SiO₂ film.

The isolation part 80 includes a trench 81 provided in the interlayer insulating film 75, a low refractive index region 82 (an example of a “first low refractive index region” of the present disclosure) provided in the trench 81, and a high refractive index region 83 (an example of a “first high refractive index region” of the present disclosure) provided in the trench 81 and in contact with the low refractive index region 82. The high refractive index region 83 sandwiches the low refractive index region 82 from both sides in the X-axis direction and the Y-axis direction.

The refractive index of the low refractive index region 82 is, for example, 1.0 or more and 1.5 or less, and is 1.2 as an example. The high refractive index region 83 has a refractive index higher than that of the low refractive index region 82. The refractive index of the high refractive index region 83 is, for example, 2 or more and 4 or less.

As illustrated in FIG. 2, the inter-pixel isolation part 51 provided in the semiconductor substrate 50 and the isolation part 80 provided in the wiring layer 70 are in contact with each other in the Z-axis direction. The isolation part 80 is provided at a position overlapping the inter-pixel isolation part 51 when viewed from the Z-axis direction.

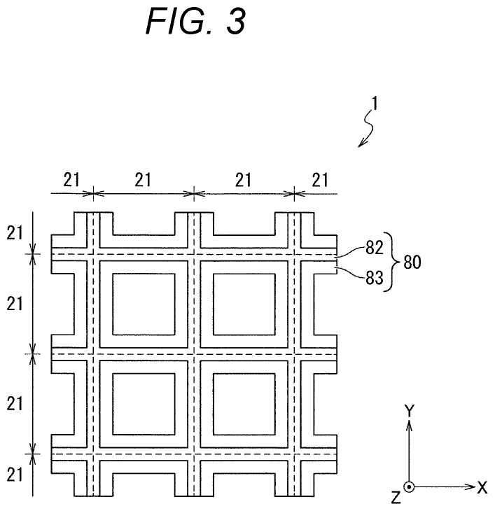

FIG. 3 is a plan view illustrating a configuration example of the isolation part 80 according to the first embodiment of the present disclosure. As illustrated in FIG. 3, the isolation part 80 is disposed so as to surround the pixel 21 when viewed from the Z-axis direction.

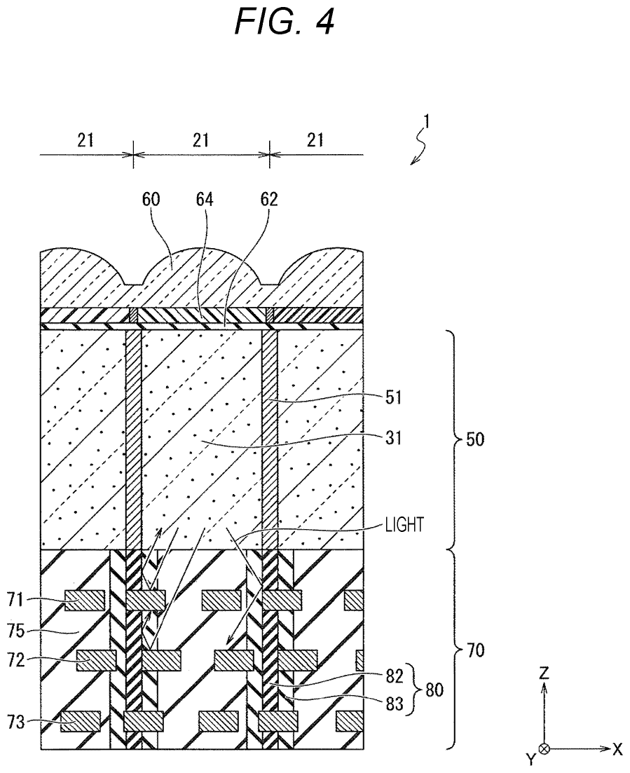

FIG. 4 is a partially enlarged cross-sectional view of the imaging device 1 according to the first embodiment of the present disclosure, and is a view illustrating a reflection example of light that has passed through the semiconductor substrate 50 and entered the wiring layer 70. As illustrated in FIG. 4, a part of the light incident on the wiring layer 70 is reflected by the surface of the wiring line (for example, the first wiring line 71 and the second wiring line 72). A part of the light reflected by the surface of the wiring line travels toward the semiconductor substrate 50 side, and the other part of the reflected light passes through the interlayer insulating film 75 and travels toward the isolation part 80 side. Furthermore, there is a case where the light that has passed through the semiconductor substrate 50 and entered the wiring layer 70 passes through the interlayer insulating film 75 and enters the isolation part 80 without being reflected by the surface of the wiring line.

As described above, the isolation part 80 includes the low refractive index region 82 and the high refractive index region 83 sandwiching the low refractive index region 82 from both sides. In a case where the refractive index of the high refractive index region 83 is higher than the refractive index of the interlayer insulating film 75 (for example, in a case where the refractive index of the interlayer insulating film 75 is about 1.46 and the refractive index of the high refractive index region 83 is 2 or more), the light transmitted through the interlayer insulating film 75 and reaching the isolation part 80 is transmitted through the high refractive index region 83 of the isolation part 80 and reaches the surface of the low refractive index region 82. The light that has reached the surface of the low refractive index region 82 is reflected at a boundary between the high refractive index region 83 and the low refractive index region 82 due to a difference in refractive index between the high refractive index region 83 and the low refractive index region 82.

Therefore, the isolation part 80 can suppress the light incident on the one pixel 21 from entering the another pixel 21 through the wiring layer 70. By including the isolation part 80, the imaging device 1 can easily confine the light incident on the one pixel 21 in the one pixel 21, which enables the color mixing between the pixels 21 to be suppressed.

Furthermore, the isolation part 80 can reflect a part of the light incident on the region surrounded by the isolation part 80 to the photodiode 31 located immediately above this region. Because the light incident on the photodiode 31 is photoelectrically converted, the imaging device 1 can improve imaging sensitivity.

Furthermore, not only the isolation part 80 but also the inter-pixel isolation part 51 is arranged so as to surround the photodiode 31 for every pixel 21. In this example, the inter-pixel isolation part 51 penetrates between the back surface 50a and the front surface 50b of the semiconductor substrate 50, and one end thereof is in contact with the isolation part 80. In the semiconductor substrate 50, the inter-pixel isolation part 51 isolates adjacent pixels 21 without a gap. Therefore, the imaging device 1 can easily confine the light in the pixel 21, which enables the color mixing between the pixels 21 to be further suppressed.

(Manufacturing Method)

Next, a manufacturing method of the imaging device 1 illustrated in FIGS. 2 to 4 is described. The imaging device 1 is manufactured by using various devices such as a film formation device (including a chemical vapor deposition (CVD) device, a sputtering device, and a thermal oxidation device), an exposure device, an etching device, and a CMP device. Hereinafter, these devices are collectively referred to as manufacturing devices. The wiring layer 70 of the imaging device 1 can be manufactured by a manufacturing method described below.

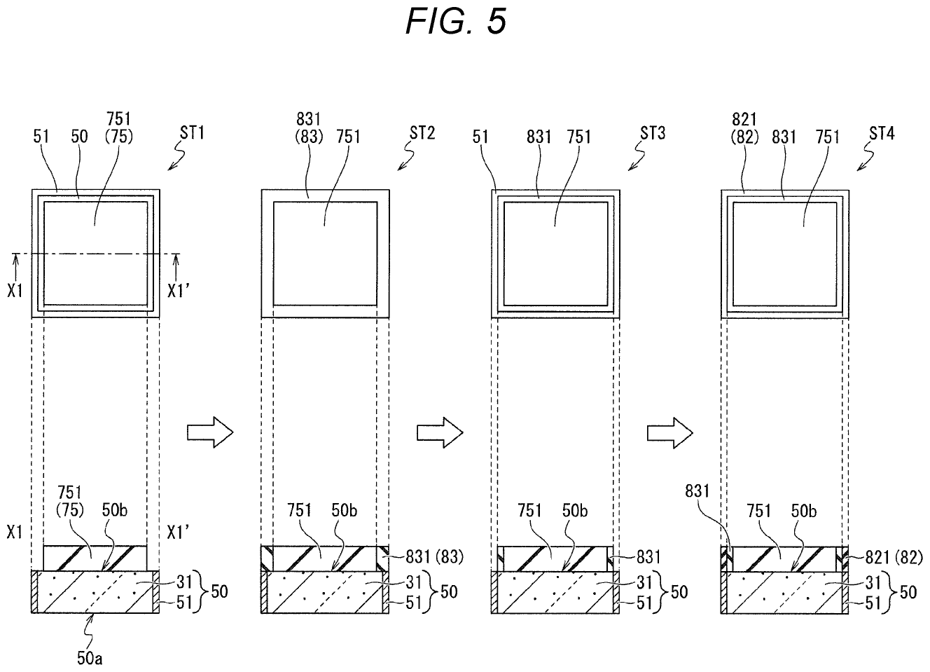

FIGS. 5 to 7 are cross-sectional views illustrating the manufacturing method of the imaging device 1 according to the first embodiment of the present disclosure in order of steps. Note that, in each step in FIGS. 5 to 7, the cross-sectional view on the lower side shows a cross section of the plan view on the upper side taken along a line X1-X1′. In the cross-sectional view on the lower side, the back surface 50a of the semiconductor substrate 50 faces downward, and the front surface 50b faces upward. Furthermore, FIGS. 5 to 7 illustrate one pixel among the plurality of pixels included in the imaging device 1.

In step ST1 in FIG. 5, the semiconductor substrate 50 in which the photodiode 31 and the inter-pixel isolation part 51 are formed is prepared. The manufacturing device forms a first insulating film 751 to be a part of the interlayer insulating film 75 on the front surface 50b of the semiconductor substrate 50 on which the photodiode 31 is formed. For example, the first insulating film 751 includes a SiO₂ film. Next, the manufacturing device partially etches the first insulating film 751 to expose the inter-pixel isolation part 51 of the semiconductor substrate 50 and a peripheral portion thereof from below the first insulating film 751.

Next, as illustrated in step ST2 in FIG. 5, the manufacturing device forms a first high refractive index film 831 to be a part of the high refractive index region 83 on the inter-pixel isolation part 51 of the semiconductor substrate 50 and the peripheral portion thereof. For example, the manufacturing device forms the first high refractive index film 831 on the entire upper side of the front surface 50b of the semiconductor substrate 50, partially etches (that is, patterns) the first high refractive index film 831 by photolithography and dry etching technology, and leaves the first high refractive index film 831 only on the inter-pixel isolation part 51 and the peripheral portion thereof. Alternatively, the manufacturing device may form the first high refractive index film 831 on the entire upper side of the front surface 50b of the semiconductor substrate 50, perform the CMP processing on the surface of the first high refractive index film 831, and leave the first high refractive index film 831 only on the inter-pixel isolation part 51 and the peripheral portion thereof.

Next, as illustrated in step ST3 in FIG. 5, the manufacturing device partially etches the first high refractive index film 831 to expose the inter-pixel isolation part 51 from below the first high refractive index film 831.

Next, as illustrated in step ST4 in FIG. 5, the manufacturing device forms a first low refractive index film 821 to be a part of the low refractive index region 82 on the inter-pixel isolation part 51 of the semiconductor substrate 50. For example, the manufacturing device may form the first low refractive index film 821 on the entire upper side of the front surface 50b of the semiconductor substrate 50, partially etches the first low refractive index film 821, and leave the first low refractive index film 821 only on the inter-pixel isolation part 51 and the peripheral portion thereof. Alternatively, the manufacturing device may form the first low refractive index film 821 on the entire upper side of the front surface 50b of the semiconductor substrate 50, perform the CMP processing on the surface of the first low refractive index film 821, and leave the first low refractive index film 821 only on the inter-pixel isolation part 51 and the peripheral portion thereof.

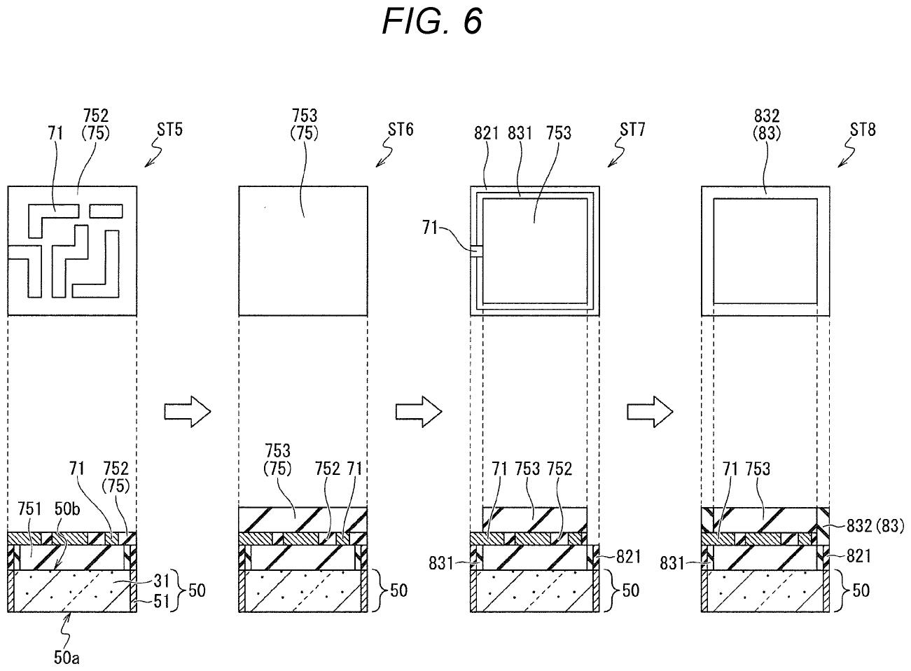

Next, as shown in step ST5 in FIG. 6, the manufacturing device forms a wiring line (for example, the first wiring line 71) on the first insulating film 751. For example, the manufacturing apparatus forms a metal film on the first insulating film 751. The vapor deposition or sputtering method is used for the method of forming the metal film. Next, the manufacturing device partially etches the metal film to form the first wiring line 71 including the metal film.

Next, the manufacturing device forms a second insulating film 752 to be a part of the interlayer insulating film 75 on the first insulating film 751 on which the first wiring line 71 is formed. For example, the second insulating film 752 includes a SiO₂ film. Next, the manufacturing device performs the CMP processing on the surface of the second insulating film 752 to planarize the second insulating film 752 and expose the first wiring line 71 from below the second insulating film 752.

Next, as illustrated in step ST6 in FIG. 6, the manufacturing device forms a third insulating film 753 to be a part of the interlayer insulating film 75 on the second insulating film 752. For example, the third insulating film 753 includes a SiO₂ film.

Next, as illustrated in step ST7 in FIG. 6, the manufacturing device partially etches the second insulating film 752 and the third insulating film 753 to expose the first high refractive index film 831 and the first low refractive index film 821 from below the third insulating film 753 and the second insulating film 752. Note that, in step ST7 in FIG. 6, a case where a part of the first wiring line 71 is disposed on the first high refractive index film 831 and the first low refractive index film 821 is illustrated. In this case, when the second insulating film 752 is etched, the first wiring line 71 serves as an etching stopper (that is, the etching ratio of the first wiring line 71 is sufficiently lower than that of the second insulating film 752). Therefore, as illustrated on the left side in the cross-sectional view of step ST7, the first wiring line 71 on the first high refractive index film 831 and the first low refractive index film 821 is left as it is without being etched downward in a state where the surface thereof are exposed.

Next, as illustrated in step ST8 in FIG. 6, the manufacturing device forms a second high refractive index film 832 to be a part of the high refractive index region 83 on the inter-pixel isolation part 51 of the semiconductor substrate 50 and the peripheral portion thereof. The method of forming the second high refractive index film 832 is, for example, the same as the method of forming the first high refractive index film 831. As illustrated on the left side in the cross-sectional view of step ST8, in a case where a part of the first wiring line 71 is disposed on the inter-pixel isolation part 51 and the peripheral portion thereof, the second high refractive index film 832 is formed on the first wiring line 71.

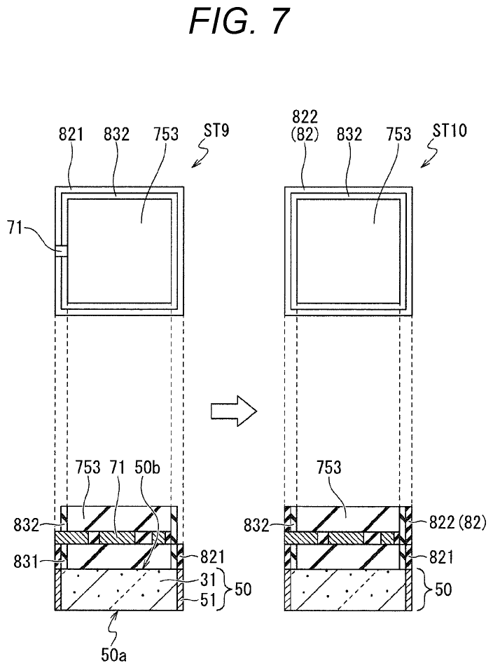

Next, as illustrated in step ST9 in FIG. 7, the manufacturing device partially etches the second high refractive index film 832 to expose the first low refractive index film 821 or the first wiring line 71 from below the second high refractive index film 832.

Next, as illustrated in step ST10 in FIG. 7, the manufacturing device forms the second low refractive index film 822 to be a part of the low refractive index region 82 on the first low refractive index film 821 exposed from below the second high refractive index film 832 or on the first wiring line 71 exposed from below the second high refractive index film 832.

The method of forming the second low refractive index film 822 is, for example, the same as the method of forming the first low refractive index film 821.

Thereafter, steps ST5 to ST10 are repeated according to the number of laminated wiring lines. Through such steps, the imaging device 1 illustrated in FIGS. 2 to 4 is completed. As shown in step ST10 in FIG. 7, in this manufacturing method, it is possible to dispose a part of the wiring line (for example, the first wiring line 81) so as to penetrate the isolation part 80.

(Effect of First Embodiment)

As described above, the imaging device 1 according to the first embodiment of the present disclosure includes the semiconductor substrate 50 having the plurality of photodiodes 31, the microlenses 60 provided on the back surface 50a side of the semiconductor substrate 50, and the wiring layer 70 provided on the opposite side of the back surface 50a of the semiconductor substrate 50. The semiconductor substrate 50 includes the inter-pixel isolation part 51 disposed between one photodiode 31 and the other photodiode 31 adjacent to each other among the plurality of photodiodes 31. The wiring layer 70 includes the isolation part 80 disposed at a position facing the inter-pixel isolation part 51. The isolation part 80 includes the low refractive index region 82 and the high refractive index region 83 in contact with the low refractive index region 82. The high refractive index region 83 sandwiches the low refractive index region 82 from both sides.

With this arrangement, the light incident on the high refractive index region 83 of the isolation part 80 is reflected at a boundary between the high refractive index region 83 and the low refractive index region 82 due to a difference in the refractive index between the high refractive index region 83 and the low refractive index region 82. Therefore, the isolation part 80 can suppress the light incident on the one pixel 21 from entering the another pixel 21 through the wiring layer 70. By including the isolation part 80, the imaging device 1 can easily confine the light incident on the one pixel 21 in the one pixel 21, which enables the color mixing between the pixels 21 to be suppressed.

### Second Embodiment

In the first embodiment described above, it has been described that a first layer including the first high refractive index film 831 and the first low refractive index film 821 is formed, a second layer including the second high refractive index film 832 and the second low refractive index film 822 is formed on the first layer, and the process is repeated a plurality of times according to the number of laminated wiring lines to form the isolation part 80 including the high refractive index region 83 and the low refractive index region 82. That is, it has been described that the film formation and the etching are repeated to form the isolation part 80 by lamination.

However, in the embodiment of the present disclosure, the manufacturing method of an isolation part 80 is not limited thereto. In the embodiment of the present disclosure, after the plurality of wiring lines is laminated, a portion of the interlayer insulating film located in the pixel isolation region may be etched to the front surface of the semiconductor substrate to form the isolation part 80. That is, the isolation part 80 may not be formed by laminating a plurality of layers, but may be formed collectively at a time.

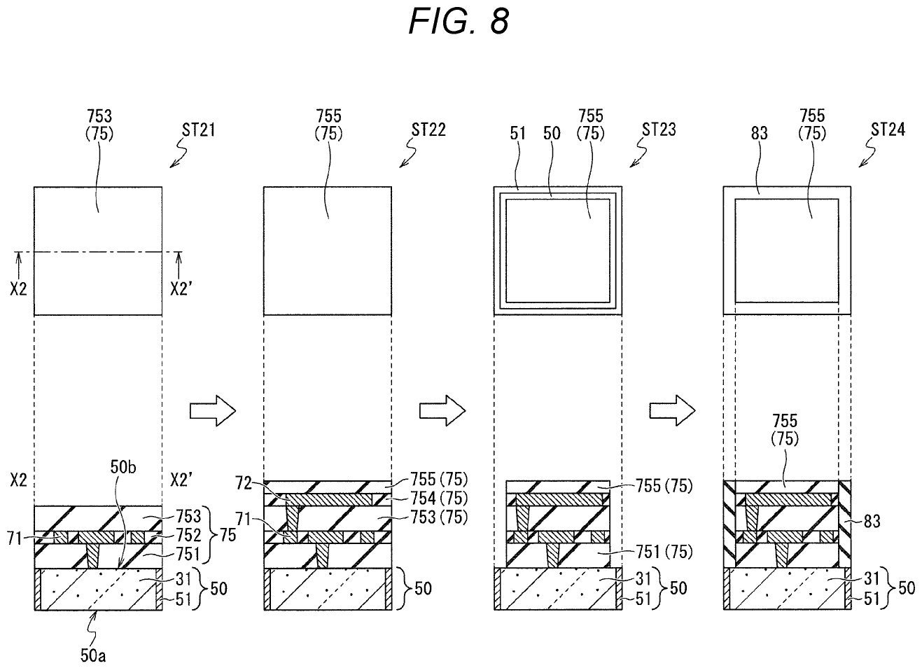

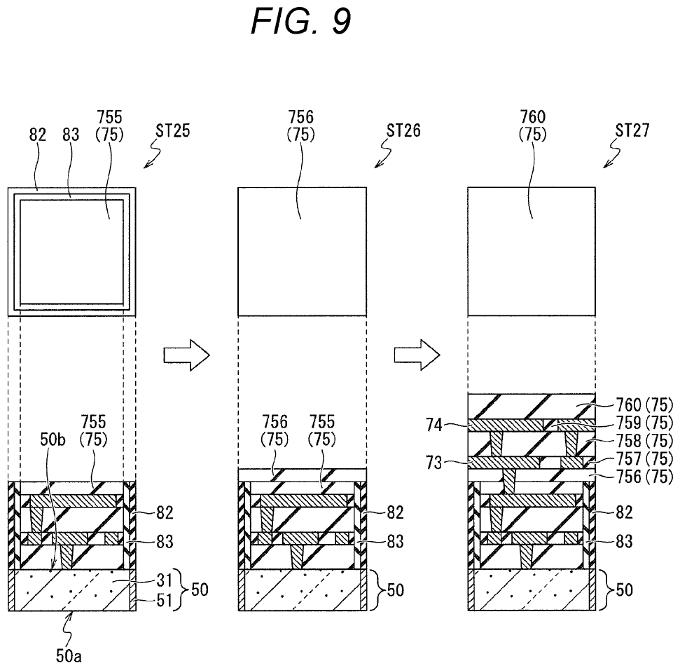

FIGS. 8 and 9 are cross-sectional views illustrating a manufacturing method of an imaging device 1 according to a second embodiment of the present disclosure. Note that, in each step in FIGS. 8 and 9, the cross-sectional view on the lower side shows a cross section of the plan view on the upper side taken along a line X2-X2′. In the cross-sectional view on the lower side, the back surface 50a of the semiconductor substrate 50 faces downward, and the front surface 50b faces upward. Furthermore, FIGS. 8 and 9 illustrate one pixel among the plurality of pixels included in the imaging device 1.

Step ST21 in FIG. 8 shows a state in which a third insulating film 753 of an interlayer insulating film 75 is formed without forming a high refractive index region 83 and a low refractive index region 82 in the inter-pixel isolation region. As shown in step ST22 in FIG. 8, the manufacturing device forms a second wiring line 72 on the third insulating film 753. The method of forming the second wiring line 72 is the same as the method of forming the first wiring line 71 described in the first embodiment.

Next, the manufacturing device forms a fourth insulating film 754 to be a part of the interlayer insulating film 75 on the third insulating film 753 on which the second wiring line 72 is formed. For example, the fourth insulating film 754 includes a SiO₂ film. Next, the manufacturing device performs the CMP processing on the surface of the fourth insulating film 754 to planarize the fourth insulating film 754 and expose the second wiring line 72 from below the fourth insulating film 754. Next, the manufacturing device forms a fifth insulating film 755 to be a part of the interlayer insulating film 75 on the fourth insulating film 754. For example, the fifth insulating film 755 includes a SiO₂ film.

Next, as illustrated in step ST23 in FIG. 8, the manufacturing device partially etches from the fifth insulating film 755 to the first insulating film 751 constituting the interlayer insulating film 75 to expose an inter-pixel isolation part 51 of the semiconductor substrate 50 and the peripheral portion thereof from below the interlayer insulating film 75.

Next, as illustrated in step ST24 in FIG. 8, the manufacturing device forms a high refractive index region 83 on the inter-pixel isolation part 51 of the semiconductor substrate 50 and the peripheral portion thereof. The method of forming the high refractive index region 83 is the same as the method of forming the first high refractive index film 831 described in the first embodiment. Next, the manufacturing device partially etches the high refractive index region 83 to expose the inter-pixel isolation part 51 from below the high refractive index region 83.

Next, as illustrated in step ST25 in FIG. 9, the manufacturing device forms a low refractive index region 82 on the inter-pixel isolation part 51 of the semiconductor substrate 50. The method of forming the low refractive index region 82 is the same as the method of forming the first low refractive index film 821 described in the first embodiment.

Thereafter, the wiring line and the insulating film are sequentially laminated according to the number of laminated wiring lines. For example, as illustrated in step ST26 in FIG. 9, the manufacturing device forms a sixth insulating film 756 to be a part of the interlayer insulating film 75 on the fifth insulating film 755. For example, the sixth insulating film 756 includes a SiO₂ film.

Next, as shown in step ST27 in FIG. 9, the manufacturing device forms a third wiring line 73 on the sixth insulating film 756. Next, the manufacturing device forms a seventh insulating film 757 to be a part of the interlayer insulating film 75. For example, the seventh insulating film 757 includes a SiO₂ film. Next, the manufacturing device performs the CMP processing on the surface of the seventh insulating film 757 to planarize the seventh insulating film 757 and expose the third wiring line 73 from below the seventh insulating film 757. Next, the manufacturing device forms an eighth insulating film 758 to be a part of the interlayer insulating film 75 on the seventh insulating film 757. For example, the eighth insulating film 758 includes a SiO₂ film.

Moreover, in a case where a fourth wiring line 74 is required, the manufacturing device sequentially performs the formation of the fourth wiring line 74, the formation of a ninth insulating film 759 to be a part of the interlayer insulating film 75 and the CMP processing of the surface thereof, and the formation of a tenth insulating film 760 to be a part of the interlayer insulating film 75. For example, each of the ninth insulating film 759 and the tenth insulating film 760 includes a SiO₂ film. Through such steps, the imaging device 1 is completed.

The manufacturing method according to the second embodiment can reduce the number of steps of the etching step of the interlayer insulating film 75, the step of forming the high refractive index region 83, and the step of forming the low refractive index region 82, as compared with the first embodiment, and thus there is a possibility that each of the manufacturing steps can be shortened and the manufacturing cost can be reduced.

Note that, in this example, the first wiring line 71 and the second wiring line 72 disposed in the region surrounded by the isolation part 80 may be used as local wiring lines connecting to the floating diffusion 33 (see FIG. 1). The first wiring line 71 and the second wiring line 72 are disposed away from the isolation part 80. The first wiring line 71 and the second wiring line 72 are not in contact with the isolation part 80 or do not penetrate the isolation part 80. Furthermore, the third wiring line 73 and the fourth wiring line 74 disposed in a region not surrounded by the isolation part 80 may be used as signal lines crossing between pixels, such as control lines. The third wiring line 73 and the fourth wiring line 74 are also disposed away from the isolation part 80.

### Third Embodiment

In the embodiment of the present disclosure, for example, at least a part of the pixel transistor such as a transfer transistor 32, an amplification transistor 34, a select transistor 35, and a reset transistor 36 (see FIG. 1) may be provided on a second semiconductor substrate different from a semiconductor substrate 50 (hereinafter, a first semiconductor substrate 50). Furthermore, an isolation layer including a low refractive index region and a high refractive index region may be disposed between the first semiconductor substrate 50 and the second semiconductor substrate.

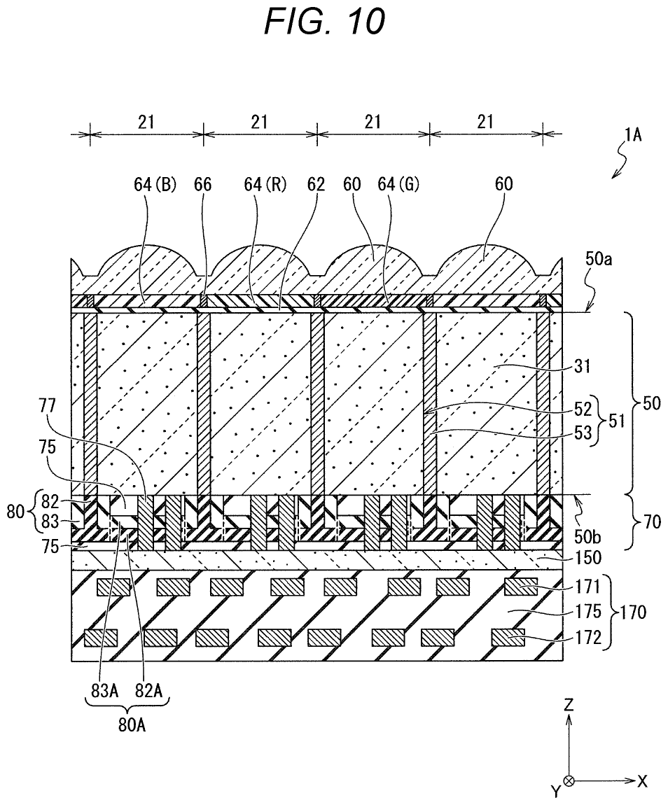

FIG. 10 is a cross-sectional view illustrating a configuration example of an imaging device 1A according to the third embodiment of the present disclosure. As illustrated in FIG. 10, the imaging device 1A according to the third embodiment further includes a second semiconductor substrate 150 facing the semiconductor substrate 50 (hereinafter, the first semiconductor substrate 50) with a wiring layer 70 interposed therebetween. The second semiconductor substrate 150 includes, for example, a silicon substrate formed by polishing a silicon wafer by the CMP. The second semiconductor substrate 150 is provided with, for example, a part of the pixel transistor such as the transfer transistor 32, the amplification transistor 34, the select transistor 35, and the reset transistor 36 (see FIG. 1).

Furthermore, in the third embodiment, the wiring layer 70 includes an interlayer insulating film 75, an isolation part 80 disposed at a position penetrating at least a part of the interlayer insulating film 75 and facing an inter-pixel isolation part 51, and an isolation part 80A (an example of a “second isolation part” of the present disclosure) disposed at a position facing the first semiconductor substrate 50 with at least a part of the interlayer insulating film 75 interposed therebetween. A photodiode 31 of each pixel 21 is covered from the side of a front surface 50b (that is, the side opposite to the light-receiving surface) of the semiconductor substrate 50 by the isolation part 80A.

For example, the isolation part 80A includes a low refractive index region 82A (an example of a “second low refractive index region” of the present disclosure) and a high refractive index region 83A (an example of a “second high refractive index region” of the present disclosure) in contact with the low refractive index region 82A. The high refractive index region 83A is located on the side closer to the semiconductor substrate 50 than the low refractive index region 82A.

The refractive index of the low refractive index region 82A is, for example, 1.0 or more and 1.5 or less, and is 1.2 as an example. The high refractive index region 83A has a refractive index higher than that of the low refractive index region 82A. The refractive index of the high refractive index region 83A is, for example, 2 or more and 4 or less.

With this arrangement, the light incident on the high refractive index region 83A of the isolation part 80A is reflected at a boundary between the high refractive index region 83A and the low refractive index region 82A by a difference in the refractive index between the high refractive index region 83A and the low refractive index region 82A. Therefore, the isolation part 80A can suppress the light incident on the one pixel 21 from entering the another pixel 21 through the wiring layer 70.

Because the imaging device 1A includes the isolation part 80A in addition to the isolation part 80A, it becomes easier to confine the light in the pixel 21. Furthermore, the isolation part 80A can reflect a part of the light incident on the region surrounded by the isolation parts 80 and 80A to the photodiode 31 located immediately above this region. Because the light incident on the photodiode 31 is photoelectrically converted, the imaging device 1A can further improve imaging sensitivity.

Note that, in this example, a case is illustrated in which the isolation part 80A is integrally formed with the isolation part 80, the high refractive index region 83A of the isolation part 80A is integrally formed with the same film as the high refractive index region 83 of the isolation part 80, and the low refractive index region 82A of the isolation part 80A is integrally formed with the same film as the low refractive index region 82 of the isolation part 80. However, this is merely an example of the third embodiment. The isolation part 80A may not be integrated with the isolation part 80, and may be isolated from each other. Furthermore, the high refractive index region 83A may include a film different from the film of the high refractive index region 83, and the low refractive index region 82A may include a film different from the film of the low refractive index region 82.

Furthermore, the wiring layer 70 includes a connection wiring line 77 that penetrates the isolation part 80A and connects the first semiconductor substrate 50 and the second semiconductor substrate 150. The connection wiring line 77 electrically connects the photodiode 31 provided on the first semiconductor substrate 50 with the pixel transistor or the like provided on the second semiconductor substrate 150. The connection wiring line 77 may include a metal such as Al or Cu, or may include a high melting point metal such as tungsten (W).

Furthermore, the wiring layer 70 includes a second wiring layer 170 on the opposite side of the wiring layer 70 across the second semiconductor substrate 150. The second wiring layer 170 includes a plurality of wiring lines (for example, a first wiring line 171, a second wiring line 172, and a third wiring line 173) and an interlayer insulating film 175. The first wiring line 171, the second wiring line 172, and the third wiring line 173 are used, for example, as signal lines crossing between the pixels 21, such as control lines.

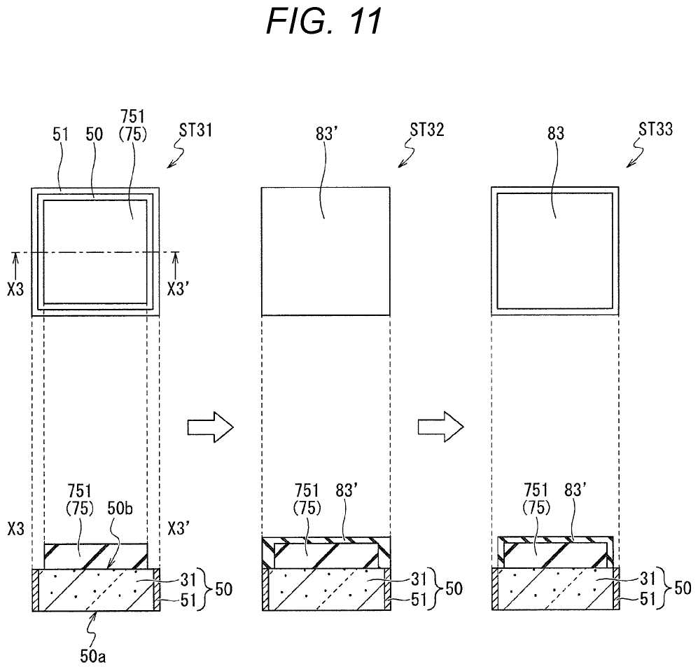

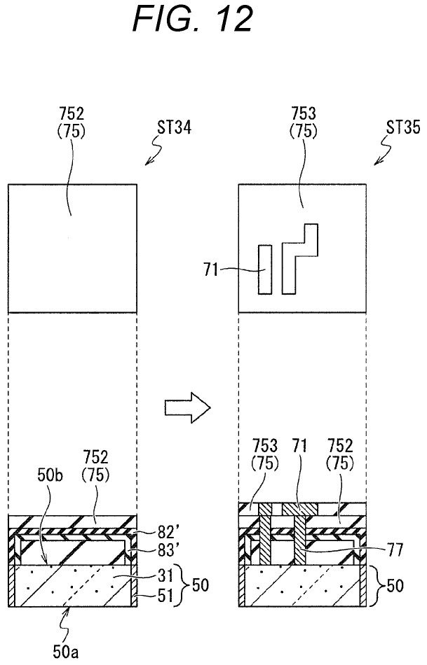

(Manufacturing method) Next, a manufacturing method of the imaging device 1A illustrated in FIG. 10 is described. FIGS. 11 and 12 are cross-sectional views illustrating the manufacturing method of the imaging device 1A according to the third embodiment of the present disclosure in order of steps. Note that, in each step in FIGS. 11 and 12, the cross-sectional view on the lower side shows a cross section of the plan view on the upper side taken along a line X3-X3′. In the cross-sectional view on the lower side, the back surface 50a of the semiconductor substrate 50 faces downward, and the front surface 50b faces upward. Furthermore, FIGS. 11 and 12 illustrate one pixel among the plurality of pixels included in the imaging device 1A.

In step ST31 in FIG. 11, the semiconductor substrate 50 in which the photodiode 31 and the inter-pixel isolation part 51 are formed is prepared. The manufacturing device forms a first insulating film 751 to be a part of the interlayer insulating film 75 on the front surface 50b of the semiconductor substrate 50 on which the photodiode 31 is formed. Next, the manufacturing device partially etches the first insulating film 751 to expose the inter-pixel isolation part 51 of the semiconductor substrate 50 and a peripheral portion thereof from below the first insulating film 751.

Next, as illustrated in step ST32 in FIG. 11, the manufacturing device forms a high refractive index film 83′ on the entire upper side of the front surface 50b of the semiconductor substrate 50. In the high refractive index film 83′, a portion located on the inter-pixel isolation part 51 of the semiconductor substrate 50 is the high refractive index region 83 (see FIG. 10), and a portion located on the first insulating film 751 is the high refractive index region 83A (see FIG. 10).

Next, as illustrated in step ST33 in FIG. 11, the manufacturing device partially etches the high refractive index film 83′ to expose the inter-pixel isolation part 51 from below the high refractive index film 83′.

Next, as illustrated in step ST34 in FIG. 12, the manufacturing device forms a low refractive index film 82′ on the entire upper side of the front surface 50b of the semiconductor substrate 50. In the low refractive index film 82′, a portion located on the inter-pixel isolation part 51 is the low refractive index region 82 (see FIG. 10), and a portion located on the first insulating film 751 is the low refractive index region 82A (see FIG. 10).

Next, the manufacturing device forms a second insulating film 752 to be a part of the interlayer insulating film 75 on the first insulating film 751. Next, as illustrated in step ST35 in FIG. 12, the manufacturing device etches the second insulating film 752, the low refractive index film 82′, the high refractive index film 83′, and the first insulating film 751 to form a through hole penetrating these films. Then, the manufacturing device forms the connection wiring line 77 by embedding metal in the through-hole.

Next, the manufacturing device forms a first wiring line 71 connecting to the connection wiring line 77 on the second insulating film 752. Next, the manufacturing device forms a third insulating film 753 to be a part of the interlayer insulating film 75 on the second insulating film 752 on which the first wiring line 71 is formed. Next, the manufacturing device performs the CMP processing on the surface of the third insulating film 753 to planarize the third insulating film 753 and expose the first wiring line 71 from below the third insulating film 753.

Thereafter, formation of the insulating film to be a part of the interlayer insulating film 75 and formation of the wiring line are repeatedly performed according to the number of laminated wiring lines. Furthermore, after the formation of the wiring layer 70, the first semiconductor substrate 50 and the second semiconductor substrate 150 are bonded together with the wiring layer 70 interposed therebetween. Through such steps, the imaging device 1A illustrated in FIG. 10 is completed.

(Effect of third embodiment) The imaging device 1A according to the third embodiment includes the isolation part 80A in addition to the isolation part 80. Therefore, the imaging device 1A can easily confine the light in the pixel 21, which enables the color mixing between the pixels 21 to be further suppressed.

<Modifications>

In the first to third embodiments described above, it has been described that the semiconductor substrate 50 is provided with the inter-pixel isolation part 51. It has been described that the inter-pixel isolation part 51 has the trench isolation structure and penetrates between the back surface 50a and the front surface 50b of the semiconductor substrate 50. In the first to third embodiments described above, the trench 511 of the inter-pixel isolation part 51 may be formed by etching from the back surface 50a to the front surface 50b side of the semiconductor substrate 50, or may be formed by etching from the front surface 50b to the back surface 50a side thereof. Furthermore, in the first to third embodiments described above, the inter-pixel isolation part 51 may not penetrate the semiconductor substrate 50.

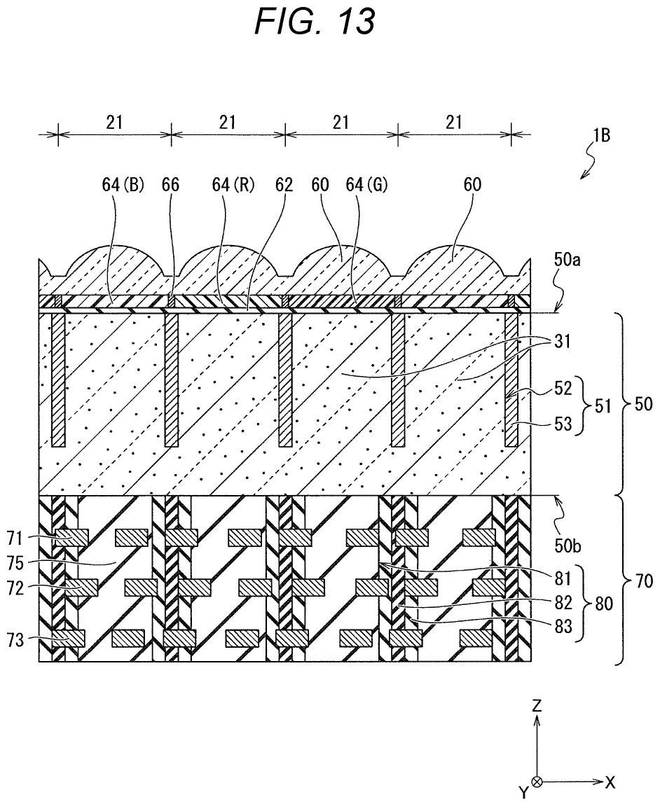

FIG. 13 is a cross-sectional view illustrating a configuration example of an imaging device 1B according to a first modification of the present disclosure. As illustrated in FIG. 13, in the imaging device 1B according to the first modification, the inter-pixel isolation part 51 does not penetrate the semiconductor substrate 50. The trench 511 of the inter-pixel isolation part 51 is formed by etching from the back surface 50a toward the front surface 50b side of the semiconductor substrate 50, but the bottom part of the trench 511 is located between the back surface 50a and the front surface 50b and does not reach the front surface 50b.

Even with such a configuration, the imaging device 1B includes the isolation part 80 in the wiring layer 70. Therefore, the imaging device 1B can easily confine the light in the pixel 21, which enables the color mixing between the pixels 21 to be suppressed.

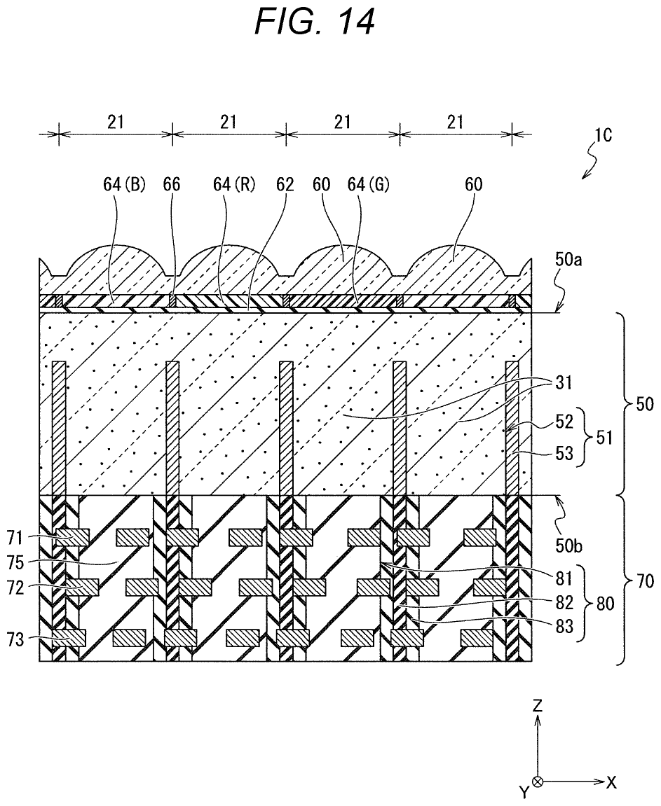

FIG. 14 is a cross-sectional view illustrating a configuration example of an imaging device 1C according to a second modification of the present disclosure. As illustrated in FIG. 14, in the imaging device 1C according to the second modification, the inter-pixel isolation part 51 does not penetrate the semiconductor substrate 50. The trench 511 of the inter-pixel isolation part 51 is formed by etching from the front surface 50b toward the back surface 50a side of the semiconductor substrate 50, but the bottom part of the trench 511 is located between the front surface 50b and the back surface 50a and does not reach the back surface 50a.

Even with such a configuration, the wiring layer 70 of the imaging device 1C includes the isolation part 80 in the wiring layer 70. Therefore, the imaging device 1C can easily confine the light in the pixel 21, which enables the color mixing between the pixels 21 to be suppressed.

### Other Embodiments

As described above, the present disclosure is described according to the embodiments and modifications thereof, but it should not be understood that the description and drawings forming a part of this disclosure limit the present disclosure. Various alternative embodiments, examples, and operation techniques will be apparent to those skilled in the art from this disclosure. It is a matter of course that the technology according to the present disclosure (present technology) includes various embodiments and the like not described herein. At least one of various omissions, substitutions, or changes of the components may be made without departing from the gist of the above-described embodiments. Furthermore, the effect described in the present description is illustrative only; the effect is not limited thereto and there may also be another effect.

Note that, the present disclosure may also have the following configuration.

(1)

An imaging device including:
a first semiconductor substrate having a plurality of photoelectric conversion elements;
a lens body provided on one surface side of the first semiconductor substrate; and
a wiring layer provided on an opposite side of the one surface of the first semiconductor substrate, in which
the first semiconductor substrate includes
an inter-element isolation part disposed between one photoelectric conversion element and another photoelectric conversion element adjacent to each other among the plurality of photoelectric conversion elements,
the wiring layer includes
a first isolation part disposed at a position facing the inter-element isolation part,
the first isolation part includes
a first low refractive index region, and
a first high refractive index region in contact with the first low refractive index region, and
the first high refractive index region sandwiches the first low refractive index region from both sides.

(2)

The imaging device according to (1), in which
the wiring layer includes:
a wiring line; and
an interlayer insulating film covering the wiring line.

(3)

The imaging device according to (2), in which the wiring line is disposed in a region surrounded by the first isolation part.

(4)

The imaging device according to (2) or (3), in which the wiring line is disposed away from the first isolation part.

(5)

The imaging device according to (2) or (3), in which a part of the wiring line penetrates the first isolation part.

(6)

The imaging device according to any one of (1) to (5), in which the inter-element isolation part and the first isolation part are in contact with each other.

(7)

The imaging device according to any one of (1) to (6), in which
the first semiconductor substrate includes another surface located on an opposite side of the one surface, and
the inter-element isolation part penetrates between the one surface and the another surface of the first semiconductor substrate.

(8)

The imaging device according to any one of (1) to (7), in which the inter-element isolation part includes a material having a refractive index different from a refractive index of the first semiconductor substrate.

(9)

The imaging device according to (1), further including
a second semiconductor substrate facing the first semiconductor substrate with the wiring layer interposed between the second semiconductor substrate and the first semiconductor substrate, in which
the wiring layer includes:
an interlayer insulating film; and
a second isolation part facing the first semiconductor substrate with at least a part of the interlayer insulating film interposed between the second isolation part and the first semiconductor substrate,
the second isolation part includes:
a second low refractive index region; and
a second high refractive index region in contact with the second low refractive index region, and
the second high refractive index region is located to a side closer to the first semiconductor substrate than the second low refractive index region.

(10)

The imaging device according to (9), in which the wiring layer includes a connection wiring line that penetrates the second isolation part and connects the first semiconductor substrate with the second semiconductor substrate.

### REFERENCE SIGNS LIST

1, 1A, 1B, 1C Imaging device
12 Pixel
13 Vertical drive circuit
14 Column signal processing circuit
15 Horizontal drive circuit
16 Output circuit
17 Control circuit
21 Pixel
22 Horizontal signal line
23 Vertical signal line
24 Data output signal line
30 Read circuit
31 Photodiode
32 Transfer transistor
33 Floating diffusion
34 Amplification transistor
35 Select transistor
36 Reset transistor
50 Semiconductor substrate (first semiconductor substrate)
50a Back surface (for example, light-receiving surface)
50b Front surface
51 Inter-pixel isolation part
60 Microlens
62 Insulating film
64 Color filter
66 Partition wall
70 Wiring layer
70 Inter-pixel isolation part
71, 171 First wiring line
72, 172 Second wiring line
73, 173 Third wiring line
74 Fourth wiring line
75, 175 Interlayer insulating film
77 Connection wiring line
80, 80A Isolation part
81 Trench
82, 82A Low refractive index region
82′ Low refractive index film
83 High refractive index region
83′ High refractive index film
83A High refractive index region
150 Second semiconductor substrate
170 Second wiring layer
511 Trench
513 Filling film
751 First insulating film
752 Second insulating film
753 Third insulating film
754 Fourth insulating film
755 Fifth insulating film
756 Sixth insulating film
757 Seventh insulating film
758 Eighth insulating film
759 Ninth insulating film
760 Tenth insulating film
821 First low refractive index film
822 Second low refractive index film
831 First high refractive index film
832 Second high refractive index film

1. An imaging device comprising:
a first semiconductor substrate having a plurality of photoelectric conversion elements;
a lens body provided on one surface side of the first semiconductor substrate; and
a wiring layer provided on an opposite side of the one surface of the first semiconductor substrate, wherein
the first semiconductor substrate includes
an inter-element isolation part disposed between one photoelectric conversion element and another photoelectric conversion element adjacent to each other among the plurality of photoelectric conversion elements,
the wiring layer includes
a first isolation part disposed at a position facing the inter-element isolation part,
the first isolation part includes
a first low refractive index region, and
a first high refractive index region in contact with the first low refractive index region, and
the first high refractive index region sandwiches the first low refractive index region from both sides.

2. The imaging device according to claim 1, wherein
the wiring layer includes:
a wiring line; and
an interlayer insulating film covering the wiring line.

3. The imaging device according to claim 2, wherein the wiring line is disposed in a region surrounded by the first isolation part.

4. The imaging device according to claim 2, wherein the wiring line is disposed away from the first isolation part.

5. The imaging device according to claim 2, wherein a part of the wiring line penetrates the first isolation part.

6. The imaging device according to claim 1, wherein the inter-element isolation part and the first isolation part are in contact with each other.

7. The imaging device according to claim 1, wherein
the first semiconductor substrate includes another surface located on an opposite side of the one surface, and
the inter-element isolation part penetrates between the one surface and the another surface of the first semiconductor substrate.

8. The imaging device according to claim 1, wherein the inter-element isolation part includes a material having a refractive index different from a refractive index of the first semiconductor substrate.

9. The imaging device according to claim 1, further comprising
a second semiconductor substrate facing the first semiconductor substrate with the wiring layer interposed between the second semiconductor substrate and the first semiconductor substrate, wherein
the wiring layer includes:
an interlayer insulating film; and
a second isolation part facing the first semiconductor substrate with at least a part of the interlayer insulating film interposed between the second isolation part and the first semiconductor substrate,
the second isolation part includes:
a second low refractive index region; and
a second high refractive index region in contact with the second low refractive index region, and
the second high refractive index region is located to a side closer to the first semiconductor substrate than the second low refractive index region.

10. The imaging device according to claim 9, wherein the wiring layer includes a connection wiring line that penetrates the second isolation part and connects the first semiconductor substrate with the second semiconductor substrate.
